(19) United States
(12) Patent Application Publication
(10) Pub. No.: US 2026/0194826 A1
(43) Pub. Date: Jul. 9, 2026

(54) DOSE ERROR CHECKING DEVICE AND METHOD OF CHECKING A DOSE ERROR

(71) Applicant: Samsung Electronics Co., Ltd., Suwon-si (KR)

(72) Inventors: Junhyeok Park, Suwon-si (KR); Minseok Kim, Suwon-si (KR); Sangbeom Park, Suwon-si (KR); Yoonsang Lee, Suwon-si (KR); Boram Jeong, Suwon-si (KR); Ahryeon Choi, Suwon-si (KR); Sangmin Hwang, Suwon-si (KR); Gilhwan Kim, Suwon-si (KR); Yohwan Joo, Suwon-si (KR)

(21) Appl. No.: 19/260,923

(22) Filed: Jul. 7, 2025

(30) Foreign Application Priority Data
Jan. 6, 2025 (KR) 10-2025-0001567

(51) Int. Cl. G03F 7/00; G01R 21/133; G06N 3/08; G06T 5/70; G06T 7/00; G06T 11/20

(52) U.S. Cl. CPC G03F 7/705; G01R 21/133; G03F 7/70033; G03F 7/70508; G03F 7/70558; G03F 7/7085; G06N 3/08; G06T 5/70; G06T 7/0004; G06T 11/26; G06T 2207/20084; G06T 2207/30148

(57) ABSTRACT

A dose error checking device may include a memory configured to store raw data generated by measuring dose error shots with multiple sensors, and a processing circuit configured to sort the raw data into a sensing group to generate a CNN (Convolutional Neural Network) input image, generate a CAM (Class Activation Mapping) image based on a final feature map corresponding to the CNN input image and weights for each error cause class, generate key data including rows corresponding to error risk sensor from the CAM image, display a SAM (Sensor Activation Mapping) image corresponding to the error risk sensor generated based on a key data, a selection data selecting at least one row from the key data, and the CAM image.

### CROSS-REFERENCE TO RELATED APPLICATION

This application claims priority to and the benefit of Korean Patent Application No. 10-2025-0001567 filed with the Korean Intellectual Property Office on Jan. 6, 2025 under 35 U.S.C. § 119, the entire contents of which are incorporated herein by reference.

### BACKGROUND OF THE INVENTION

Dose refers to the amount of EUV (Extreme Ultraviolet) light that penetrates the wafer, and is a parameter used in the semiconductor manufacturing process. The precise amount of EUV light is desired to form a fine circuit pattern on the wafer. Dose error refers to an error that occurs when the amount of EUV light transmitted through the wafer differs from an expected amount during the EUV exposure process.

Minimizing dose errors may accurately form fine circuit patterns in semiconductor manufacturing processes, which can improve yield. Therefore, it is desired to accurately analyze the cause by systematically classifying the cause of dose errors.

### SUMMARY

The present disclosure relates to a dose error checking device and an operating method thereof.

The present disclosure attempts to provide inspection device of dose error and operating method.

One embodiment provides a dose error checking device and a checking method thereof that improve the accuracy of dose error cause analysis.

According to one embodiment of the present disclosure for solving the above technical problems, a dose error checking device may include a memory for storing raw data generated by measuring dose error shots with a plurality of sensors, a processing circuit for generating a CNN (Convolutional Neural Network) input image by arranging the raw data based on sensing groups, generating a CAM (Class Activation Mapping) image based on a final feature map corresponding to the CNN input image and weights by error cause classes, generating key data including rows corresponding to error risk sensors from the CAM image, and displaying the key data, selection data selecting at least one row from the key data, and a SAM (Sensor Activation Mapping) image generated based on the selection data and the CAM image and corresponding to the error risk sensors.

A dose error checking device according to one embodiment may include a processing circuit configured to generate a CAM image and key data including rows corresponding to error risk sensors from the CAM image based on a final feature map extracted through a convolution and pooling process for a CNN input image and weights for each dose error cause class, display selection data selecting at least one row from the key data and a SAM image generated based on the selection data and the CAM image and corresponding to the error risk sensor, analyze the cause of the dose error based on the SAM image, and provide an action to resolve the cause of the dose error.

A method for detecting dose errors according to one embodiment may include a step of generating a CNN input image by arranging raw data generated by measuring dose error shots with a plurality of sensors based on sensing groups, a step of generating a CAM image based on a final feature map corresponding to the CNN input image and weights for each error cause class, a step of generating key data including rows corresponding to error risk sensors from the CAM image, and a step of displaying the key data, selection data selecting at least one row from the key data, and a SAM image generated based on the selection data and the CAM image and corresponding to the error risk sensors.

### BRIEF DESCRIPTION OF THE DRAWINGS

FIG. 1 is a block diagram of an inspection device according to one embodiment.

FIG. 2 is a block diagram of an imaging module according to one embodiment.

FIG. 3 is a diagram illustrating a sensing group and a plurality of sensors included in the sensing group according to one embodiment.

FIG. 4 is a diagram showing the test results of a CNN input image generated based on sorted parsed data.

FIG. 5 is a block diagram of an analysis module according to one embodiment.

FIG. 6 is a partial configuration diagram included in a classifier according to one embodiment.

FIG. 7 is a block diagram included in a key data generator according to one embodiment.

FIG. 8 is a drawing showing a second CAM image according to one embodiment.

FIG. 9 is a diagram showing a filtering operation of a filtering module according to one embodiment.

FIG. 10 is a diagram showing key data according to one embodiment.

FIG. 11 is a diagram showing key data according to one embodiment.

FIG. 12 is a block diagram of a visualization module according to one embodiment.

FIG. 13 is a diagram showing the dose error rate of a shot according to one embodiment.

FIG. 14 is a diagram showing the cause of an error in a shot, the time of occurrence of a dose error, and key data according to one embodiment.

FIGS. 15 and 16 are drawings showing a first SAM image and a second SAM image, respectively.

FIG. 17 is a diagram showing the relationship between the dose margin and the driver laser gain sensor.

FIG. 18 is a diagram illustrating a portion of a labeled action according to one embodiment.

FIG. 19 is a flowchart showing a dose error checking method in one embodiment.

FIG. 20 is an example block diagram illustrating a computer device according to one embodiment.

### DETAILED DESCRIPTION

Below, with reference to the attached drawings, embodiments of the present disclosure are described in detail so that a person having ordinary skill in the art to which the present disclosure pertains may easily practice the present disclosure. As those skilled in the art would realize, the described embodiments may be modified in various different ways, all without departing from the spirit or scope of the present disclosure. However, the present disclosure may be implemented in various different forms and is not limited to the embodiments described herein. Accordingly, the drawings and description are to be regarded as illustrative in nature and not restrictive. Like reference numerals designate like elements throughout the specification. And in order to clearly explain the present disclosure in the drawings, parts that are not related to the explanation are omitted, and similar parts are given similar drawing reference numerals throughout the specification. In the flowchart described with reference to the drawings, the order of operations may be changed, several operations may be merged, some operations may be split, and certain operations may not be performed.

Additionally, expressions written in the singular may be interpreted as singular or plural, unless explicit expressions such as \ “one\” or \ “singular\” are used. Terms that include ordinal numbers, such as first, second, etc., may be used to describe various components, but the components are not limited by these terms. These terms may be used to distinguish one component from another.

Hereinafter, the present disclosure will be described in more detail through examples. These examples are intended only to illustrate the present disclosure, and the scope of protection of the rights of the present disclosure is not limited by these examples.

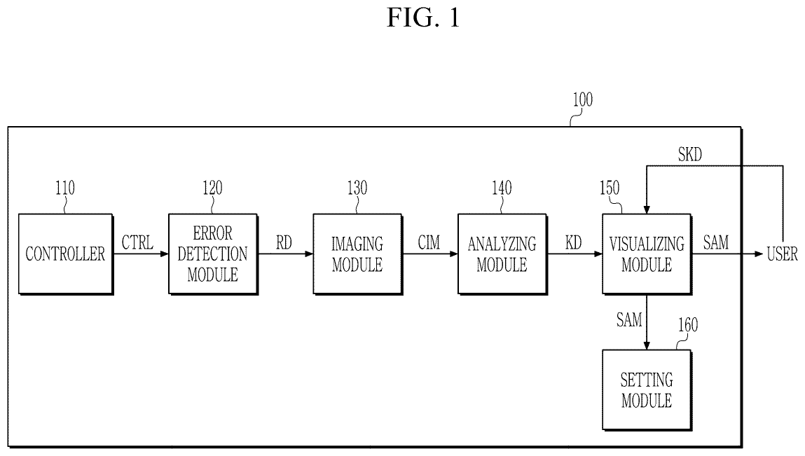

FIG. 1 is a block diagram of a dose error checking device according to one embodiment.

Referring to FIG. 1, a dose error checking device 100 may inspect the cause of a dose error of a shot that occurs during a photo process. In the photo process, dose errors may occur if the shot is exposed to too much or too little EUV (Extreme Ultra Violet). If a dose error occurs, the wafer may not form an accurate pattern, which may result in reduced yield. Dose error causes may include plasma oscillation, seed laser pulse loss (SEED LASER PP DROPOUT), DDM (Dynamic Dose Monitor) triggering instability, and unintended EUV detected.

A dose error detection device (100) may detect a sensor that generates a dose error. Dose errors may be caused by sensor malfunction. A sensor malfunction could indicate a malfunction in a specific module or hardware. The dose error checking device 100 may provide the user USER with an action to resolve the dose error. The dose error checking device 100 may be integrated and operated in an EUV facility. The dose error checking device 100 may include a controller 110, an error detection module 120, an imaging module 130, an analysis module 140, a visualization module 150, and a setting module 160.

The controller 110 may control the operation of the dose error checking device 100. The controller 110 may periodically transmit a control signal CTRL to the error detection module 120. A series of operations between modules within the dose error checking device 100 may be performed based on the control signal CTRL. The controller 110 may receive a separate control signal from an external host device and generate a control signal CTRL based on the control signal.

The error detection module 120 may receive a control signal CTRL from the controller 110. The error detection module 120 may detect a dose error of a shot based on a control signal CTRL. The error detection module 120 may calculate the dose error rate of the shot. The error detection module 120 may determine the cause of an error in a shot.

The error detection module 120 may generate raw data RD, which is time series data for 300 to 400 sensors, when a dose error occurs in a shot. Dose errors may occur approximately 3152 times per day. Accordingly, the data capacity of raw data RD may be approximately 113.47 GB. Raw data RD generated by measuring dose error shots with multiple sensors may be stored in memory. The error detection module 120 may transmit raw data RD to the imaging module 130.

The imaging module 130 may receive raw data RD from the error detection module 120. The imaging module 130 may sort raw data RD based on multiple sensing groups. Multiple sensing groups may each include multiple sensors. Multiple sensors may be grouped into multiple sensing groups based on the sensing targets they each want to detect.

The imaging module 130 may align time series data for multiple sensors included in the same sensing group so that sensors with the same physical unit are adjacent to each other. The imaging module 130 may convert raw data RD into a CNN (Convolutional Neural Network) input image CIM and transmit it to the analysis module 140.

The analysis module 140 may receive a CNN input image CIM from the imaging module 130. The analysis module 140 may extract a final feature map through a convolution and pooling process targeting a CNN input image CIM. The analysis module 140 may generate a CAM (Class Activation Mapping) image by multiplying the final feature map and the weights for each error cause class. The analysis module 140 may resize the CAM image to fit the CNN input image CIM specifications. The analysis module 140 may overlay the resized CAM image on the CNN input image CIM. A CAM image may visualize the regions of the input image CIM that the CNN focused on while learning features associated with a particular class. The analysis module 140 may generate key data KD including rows corresponding to one or more error risk sensors from the CAM image. The analysis module 140 may transmit key data KD to the visualization module 150.

The visualization module 150 may receive key data KD from the analysis module 140. The visualization module 150 may display key data KD. The visualization module 150 may display at least one selection data SKD selected by a user USER among the key data KD. The visualization module 150 may display a SAM (Sensor Activation Mapping) image corresponding to an error risk sensor (e.g., a selected one from one or more error risk sensors) based on the selection data SKD and the CAM image. The visualization module 150 may transmit a SAM image SAM to the user USER and the setting module 160, respectively.

The setting module 160 may receive a SAM image SAM from the visualization module 150. The setting module 160 may analyze the cause of the dose error based on the SAM image SAM. The setting module 160 may provide actions to resolve the cause of the dose error. The setting module 160 may label actions corresponding to dose error causes as training data for CNN learning.

The controller 110, error detection module 120, imaging module 130, analysis module 140, visualization module 150, and setting module 160 may be executed through a processing circuit.

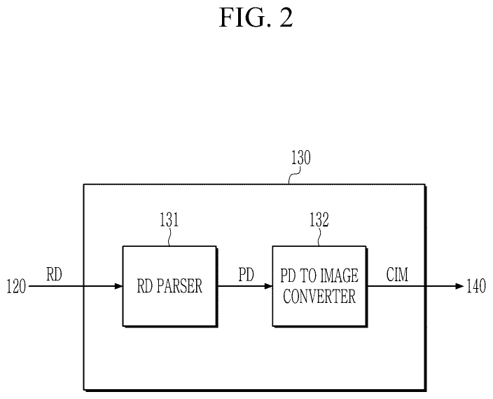

FIG. 2 is a block diagram of an imaging module according to one embodiment.

Referring to FIG. 2, the imaging module 130 may include a RD analyzer 131 and a converter 132 that converts parsed data into an image. The RD analyzer 131 may receive raw data RD from the error detection module 120. Raw data RD may be organized into semi-structured data (Semi-Structed Data). The RD analyzer 131 may parse raw data RD to generate parsed data PD in a structured form. The RD analyzer 131 may transmit parsed data PD to the converter 132.

The converter 132 may receive parsed data PD from the RD analyzer 131. The converter 132 may sort the parsed data PD based on the sensing groups. The converter 132 may align time series data for multiple sensors included in the parsed data so that sensors with the same physical unit are adjacent to each other.

The converter 132 may convert the sorted parsed data PD based on mathematical expressions 1 and 2 into a CNN input image.

$$Xstd = ( X - min ( X ) ) \div ( max ( X ) - min ( X ) ) \qquad ( EquatioN + 1 )$$

Here, Xstd may mean N rows of data (N is an integer greater than 0) included in the parsed data PD before scaling is performed, and X may mean N rows of data included in the parsed data PD. max(X) may mean the largest value among N rows of data, and min(X) may mean the smallest value among N rows of data.

$$Xscaled = Xstd \times ( 255 ) \qquad ( Equation 2 )$$

Here, Xscaled may mean N rows of data included in the parsed data PD after scaling to a size of 255. The scaling size is not limited to this.

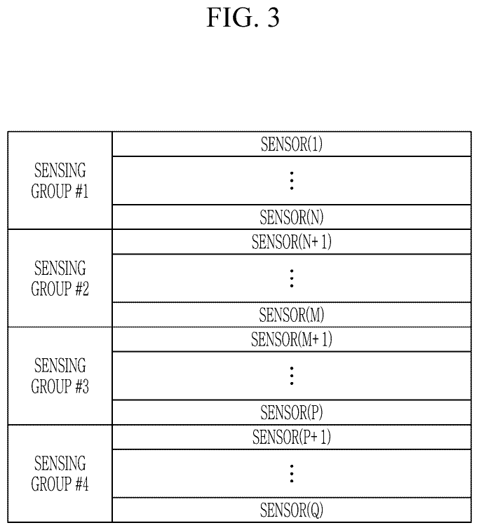

FIG. 3 is a diagram illustrating a sensing group and a plurality of sensors included in the sensing group according to one embodiment.

Referring to FIG. 3, there may be multiple sensing groups. Multiple sensing groups may each include multiple sensors. For example, a first sensing group SENSING GROUP #1 may include first to Nth sensors SENSOR(1) to SENSOR(N). A second sensing group SENSING GROUP #2 may include N+1 to M sensors SENSOR(N+1) to SENSOR(M). A third sensing group SENSING GROUP #3 may include M 1 to P sensors SENSOR (M 1) to SENSOR (P). A fourth sensing group SENSING GROUP #4 may include P 1 to Q sensors SENSOR (P 1) to SENSOR (Q). The number of sensing groups and the number of sensors included in a sensing group are not limited to the examples.

A first sensing group SENSING GROUP #1 may include a plurality of sensors that sense the action of generating a droplet and delivering the droplet to a specific location. For example, a first sensing group SENSING GROUP #1 may include an X-axis sensor that senses the X-axis distance between the laser and the droplet, a Y-axis sensor that senses the Y-axis distance between the laser and the droplet, and a Z-axis sensor that senses the Z-axis distance between the laser and the droplet.
the second sensing group SENSING GROUP #2 may include a plurality of sensors that sense the motion of monitoring the energy of the laser. For example, the second sensing group SENSING GROUP #2 may include a main pulse pedestal energy sensor that controls the main pulse pedestal energy of the laser and a main pulse power sensor that controls the output power of the main pulse of the laser.

The third sensing group SENSING GROUP #3 may include multiple sensors that sense interference between the laser and the main pulse, and between the laser and the pre-pulse. For example, the third sensing group SENSING GROUP #3 may include a first focus sensor that controls the X-axis distance between the focus of the main pulse and the focus of the pre-pulse and a second focus sensor that controls the Y-axis distance between the focus of the main pulse and the focus of the pre-pulse.

The fourth sensing group SENSING GROUP #4 may include multiple sensors that amplify the power of the seed laser and the driver laser. For example, the fourth sensing group SENSING GROUP #4 may include a driver laser gain sensor that controls the amplification intensity of the driver laser and a power amplifier gain sensor that controls the amplification capability of the power amplifier.

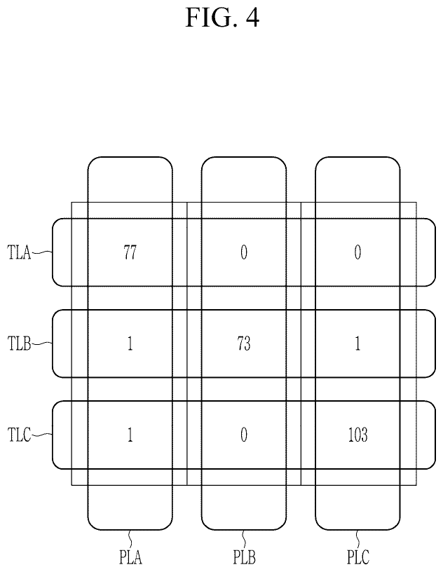

FIG. 4 is a diagram showing the test results of a CNN input image generated based on sorted parsed data.

Referring to FIG. 4, the test result of the CNN input image may be produced based on the degree of agreement between the three predicted labels PLA, PLB, and PLC for each of the three correct labels TLA, TLB, and TLC. The three correct labels TLA, TLB, and TLC may each be the cause of different dose errors. For example, the three correct labels TLA, TLB, and TLC could be Unintended EUV Detected, Dynamic Dose Monitor (DDM) triggering instability, and SEED LASER PP DROPOUT, respectively.

The accuracy rate of the first predicted label PLA may be determined based on the ratio of the number of first predicted label PLA that predicted the first correct label TLA and the number of second predicted labels PLB and third predicted labels PLC that predicted the first correct label TLA.

For example, if the number of first predicted label PLA that predicted the first correct label TLA is 77, and the number of second predicted labels PLB and third predicted labels PLC that predicted the first correct label TLA is 0, the correctness rate of the first predicted label PLA may be 100%.

If the number of second predicted labels PLB that predicted the second correct label TLB is 73, and the number of first predicted label PLA and third predicted labels PLC that predicted the second correct label TLB is 1 each, the accuracy of the second predicted label PLB may be 97.3%.

If the number of third predicted labels PLC that predicted the third correct label TLC is 103, the number of first predicted label PLA that predicted the third correct label TLC is 1, and the number of third predicted label PLC that predicted the third correct label TLC is 0, the accuracy of the third predicted label PLC may be 99.0%.

The accuracy rates of the three predicted labels PLA, PLB, and PLC are all over 97%. When testing against CNN input images generated based on parsed data sorted by sensing group and physical units within the sensing group, the accuracy of predicting the cause of dose error may be improved.

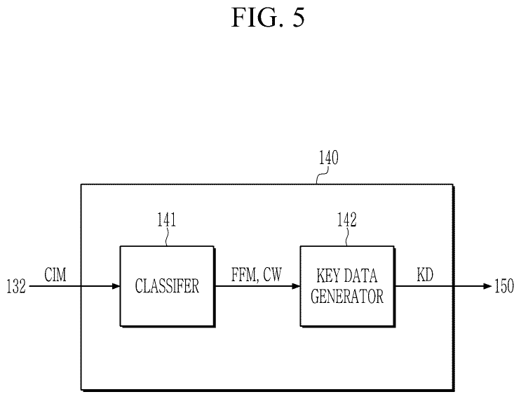

FIG. 5 is a block diagram of an analysis module according to one embodiment.

Referring to FIG. 5, the analysis module 140 may include a classifier 141 and a key data generator 142. The classifier 141 may receive a CNN input image CIM from the converter 132. The classifier 141 may extract a final feature map FFM through a convolution and pooling process for the CNN input image. The classifier 141 may classify the cause of the shot's dose error by multiplying the average value of the final feature map FFM by an error cause class-specific weight CW for each error cause class. The classifier 141 may transmit the final feature map FFM and error cause class-specific weight CW to the key data generator 142.

The key data generator 142 may generate a CAM image by multiplying the final feature map FFM by the error cause class-specific weight CW for each error cause class. The key data generator 142 may generate key data KD having a value greater than or equal to a first reference value in a CAM image. The key data generator 142 may transmit key data KD to the visualization module 150.

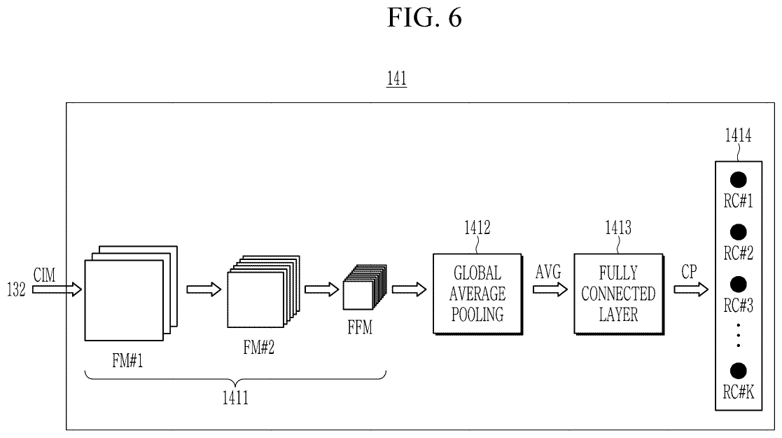

FIG. 6 is a partial configuration diagram included in a classifier according to one embodiment.

Referring to FIG. 6, the classifier 141 may include a feature map extraction unit 1411, a global average pooling unit 1412, a fully connected layer unit 1413, and an error cause class space 1414. The feature map extraction unit 1411 may receive a CNN input image CIM from the converter 132. The feature map extraction unit 1411 may extract a feature map through convolution, pooling, and RELU processes.

The feature map extraction unit 1411 may perform convolution to generate a feature map by applying a kernel to a CNN input image CIM. The feature map extraction unit 1411 may perform a pooling operation to reduce the size of a feature map generated by convolution. Pooling operations may include max pooling and average pooling. Max pooling may reduce the size of the feature map by selecting the largest value in the local filter area of the feature map generated by convolution. Average pooling may reduce the size of a feature map based on the average value of the local filter region of the feature map generated by the convolution operation.

The feature map extraction unit 1411 may introduce non-linearity into the feature map through RELU (Rectified Linear Unit). RELU is an activation function that outputs the input value as is if the input value is positive, and outputs 0 if the input value is negative. By using RELU in the feature map extraction unit 1411, nonlinear characteristics may be added to the feature map. Accordingly, CNN may learn patterns and characteristics of complex data.

The convolution, pooling, and RELU usage operations of the feature map extraction unit 1411 may be repeated multiple times as one continuous process. Based on the first convolution, pooling, and RELU usage operations, the feature map extraction unit 1411 may generate a first feature map FM #1. The feature map extraction unit 1411 may perform additional convolution, pooling, and RELU usage operations on the first feature map FM #1 to generate a second feature map FM #2. Finally, through the above continuous process, the feature map extraction unit 1411 may generate a final feature map FFM. The feature map extraction unit 1411 may transfer the final feature map FFM to the global average pooling unit 1412.

The global average pooling unit 1412 may receive the final feature map FFM from the feature map extraction unit 1411. The global average pooling unit 1412 may compress the final feature map FFM. The global average pooling unit 1412 may compress the entire filter area of the final feature map FFM to an average value AVG. The global average pooling unit 1412 may pass the average value AVG to the fully connected layer unit 1413.

The fully connected layer unit 1413 may receive an average value AVG from the global average pooling unit 1412. The fully connected layer unit 1413 may calculate a probability for each error cause class CP by multiplying the average value AVG and the error cause class-specific weight CW for each error cause class. The fully connected layer unit 1413 may transfer the probability for each error cause class CP to the error cause class space 1414.

The error cause class space 1414 may include Multiple error cause classes RC #1, RC #2, RC #3, . . . . RC #K. Multiple error cause classes RC #1, RC #2, RC #3, . . . . RC #K may be classes representing different types of error causes.

The error cause class space 1414 may receive the probability for each error cause class CP from the fully connected layer unit 1413. The error cause class space 1414 may receive the probability for each error cause class CP corresponding to Multiple error cause classes RC #1, RC #2, RC #3, . . . . RC #K. If the probability for each error cause class CP is greater than or equal to the first criterion, the corresponding error cause class may be output as a dose error cause. For example, an error cause class corresponding to the probability for each error cause class CP of 0.5 or greater may be output as a dose error cause.

For example, if the first error cause class is unintentional EUV detection, the second error cause class is seed laser pulse loss, and the third error cause class is DDM triggering instability, and the error cause class-specific probability of the first error cause class is 0.14, the error cause class-specific probability of the second error cause class is 0.11, and the error cause class-specific probability of the third error cause class is 0.70, then DDM triggering instability may be output as the dose error cause.

The analysis module 140 may generate a feature map based on a PRE TRAINED CNN model that has been pre-trained for EUV energy time series data. Using a PRE TRAINED CNN model may shorten the training time by utilizing already learned weights and features. PRE TRAINED CNN models may include VGGNET, GoogLeNet, ResNet, and EfficientNet.

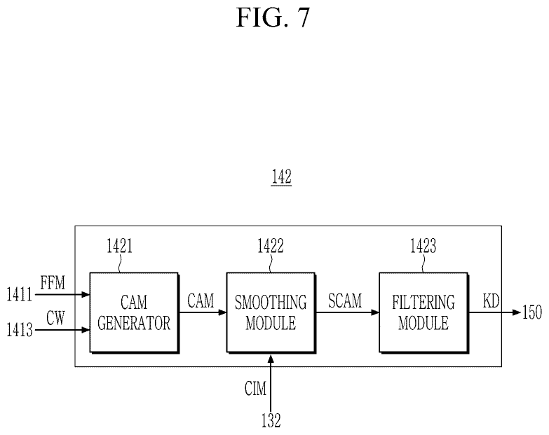

FIG. 7 is a block diagram included in a key data generator according to one embodiment.

Referring to FIG. 7, the key data generator 142 may include a CAM generator 1421, a smoothing module 1422, and a filtering module 1423. The CAM generator 1421 may receive a final feature map FFM from the feature map extraction unit 1411. The CAM generator 1421 may receive error cause class-specific weight CW from the fully connected layer unit 1413. The CAM generator 1421 may produce multiple second final feature maps by multiplying the final feature map FFM by error cause class-specific weight CW for each error cause class. The CAM generator 1421 may generate a CAM image CAM for a CNN input image by combining multiple second final feature maps. The CAM generator 1421 may transmit a CAM image CAM to a smoothing module 1422.

The smoothing module 1422 may receive a CAM image CAM from the CAM generator 1421. The smoothing module 1422 may receive a CNN input image CIM from a converter 132 described with reference to FIG. 2. Since the CAM image CAM is generated through convolution and pooling operations, its image size may be smaller than the CNN input image CIM. The smoothing module 1422 may resize the CAM image CAM according to the specifications of the CNN input image CIM. The smoothing module 1422 may overlay the resized CAM image onto the CNN input image CIM to generate an overlaid image. The difference between the CAM image CAM and the CNN input image may be clearly seen in the overlapping images.

The smoothing module 1422 may smooth the overlapping images by applying Gaussian blur. Gaussian blur may be expressed by the mathematical expression 3, which represents the Gaussian distribution.

$$f ( x \vert μ , σ ) = \frac{1}{\sqrt{2 πσ}} \times exp ( - \frac{{( x - μ )}^{2}}{2 {σ}^{2}} ) \qquad ( Equation 3 )$$

Here, x represents the distance from the center of the Gaussian blur, μ represents the center value of the Gaussian blur, and σ2 represents the variance of the Gaussian blur.

The smoothing module 1422 may convert the overlapping image into a second CAM image SCAM by applying Gaussian blur. The second CAM image SCAM may be expressed in a refined form with reduced noise generated during the CAM image CAM generation process. The second CAM image SCAM may be processed visually and naturally by smoothly converting the detailed differences between the CAM image CAM and the CNN input image CIM. The smoothing module 1422 may pass the second CAM image SCAM to the filtering module 1423.

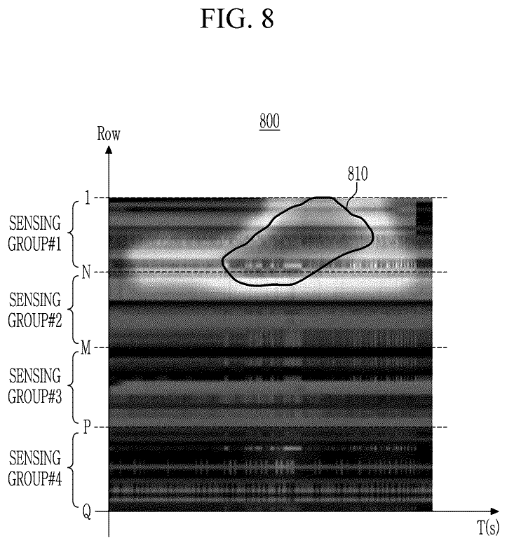

FIG. 8 is a drawing showing a second CAM image according to one embodiment.

Referring to FIG. 8, a second CAM image 800 may be generated by applying Gaussian blur to the overlapping image of FIG. 7. The second CAM image 800 may display values of time series data of a plurality of sensors SENSOR(1) to SENSOR(Q) included in each of a plurality of sensing groups SENSOR GROUP #1, SENSOR GROUP #2, SENSOR GROUP #3, and SENSOR GROUP #4. A first region 810 in which the values of time series data of multiple sensors SENSOR(1) to SENSOR(Q) are greater than or equal to a first reference value may be distributed to a first sensing group SENSOR GROUP #1 and a second sensing group SENSOR GROUP #2.

At least one sensor among the plurality of sensors SENSOR(1)-SENSOR(N), SENSOR(N+1)-SEONSOR(M) included in each of the first sensing group SENSOR GROUP #1 and the second sensing group SENSOR GROUP #2 may include time series data having a value greater than or equal to a first reference value.

At this time, a sensor including time series data having a value greater than or equal to the first criterion may be an error risk sensor. Each of the multiple sensors SENSOR(M 1)-SEONSOR(P), SENSOR(P 1)-SEONSOR(Q) included in the third sensing group SENSOR GROUP #3 and the fourth sensing group SENSOR GROUP #4 may include time series data having values less than the first reference value. At this time, a sensor including time series data having a value less than the first reference value may be a normal state sensor.

Again, referring to FIG. 7, the filtering module 1423 may receive a second CAM image SCAM from the smoothing module 1422. The filtering module 1423 may filter rows among the plurality of rows included in the second CAM image SCAM in which the maximum value of time series data included in each of the plurality of rows has a value greater than or equal to a first criterion. The filtering module 1423 may generate key data KD based on the filtered rows. At this time, the filtered rows may be matched to error risk sensors. An error risk sensor could mean a sensor that has a high probability of generating a dose error.

For example, the filtering module 1423 may filter only rows in which the maximum value of time series data included in each of the plurality of rows included in the second CAM image SCAM is 0.5 or greater. The filtering module 1423 may generate key data KD based on rows in which the maximum value of the time series data is 0.5 or greater. Rows in the time series data with a maximum value greater than or equal to 0.5 may be matched to the error risk sensor.

Key data KD may be sorted and separated by sensing group. Key data KD may be aligned so that sensors with the same physical unit are adjacent to each other within the same sensing group. Key data KD may be sorted based on the maximum value of the time series data contained in each of the multiple rows. The way to sort key data KD is not limited to this. The filtering module 1423 may pass the key data KD to the visualization module 150.

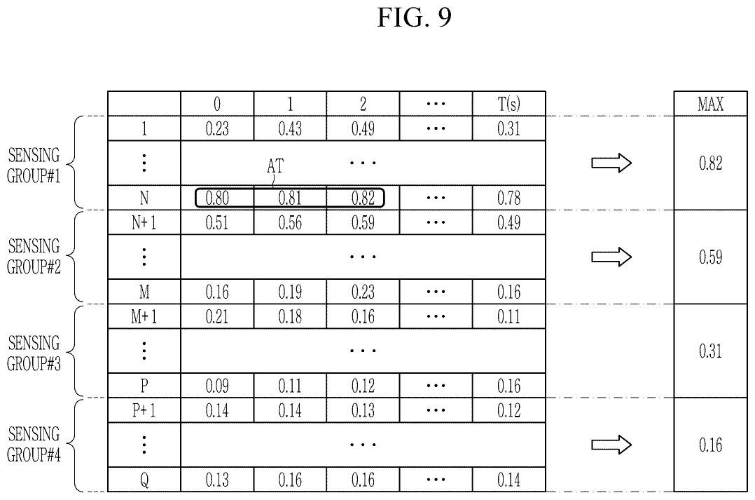

FIG. 9 is a diagram showing a filtering operation of a filtering module according to one embodiment.

Referring to FIG. 9, the filtering module 1423 described with reference to FIG. 7 may perform a filtering operation on the second CAM image SCAM described with reference to FIG. 7 sorted by a plurality of sensing groups SENSOR GROUP #1, SENSOR GROUP #2, SENSOR GROUP #3, and SENSOR GROUP #4. At this time, the second CAM image SCAM may be generated based on the CNN input images CIM described with reference to FIG. 2 sorted by multiple sensing groups SENSOR GROUP #1, SENSOR GROUP #2, SENSOR GROUP #3, and SENSOR GROUP #4.

The filtering module 1423 may filter a sensing group having a maximum value of time series data of 0.5 or greater among a plurality of sensing groups SENSOR GROUP #1, SENSOR GROUP #2, SENSOR GROUP #3, and SENSOR GROUP #4 included in the second CAM image SCAM.

For example, the maximum value of N rows of time series data included in the first sensing group SENSOR GROUP #1 may be 0.82, and the maximum value of N+1 rows of time series data included in the second sensing group SENSOR GROUP #2 may be 0.59. The filtering module 1423 may extract a first sensing group SENSOR GROUP #1 including N rows and a second sensing group SENSOR GROUP #2 including N+1 rows. The filtering module 1423 may generate key data KD described with reference to FIG. 7 based on the first sensing group SENSOR GROUP #1 and the second sensing group SENSOR GROUP #2.

The maximum value of the time series data included in the third sensing group SENSOR GROUP #3 may be 0.31, and the maximum value of the time series data included in the fourth sensing group SENSOR GROUP #4 may be 0.16. The filtering module 1423 may not extract the third sensing group SENSOR GROUP #3 and the fourth sensing group SENSOR GROUP #4.

The filtering module 1423 may obtain a sensor activation time AT corresponding to a section in which the maximum value of the time series data has a value greater than or equal to 0.5. The sensor activation time AT may refer to the activation time of a sensor that is likely to cause a dose error.

For example, the filtering module 1423 may obtain the sensor activation time AT of 0 to 2 (s) corresponding to a section having a maximum value of 0.5 or greater in time series data of N rows. The filtering module 1423 may transmit the sensor activation time AT to the visualization module 150 described with reference to FIG. 1.

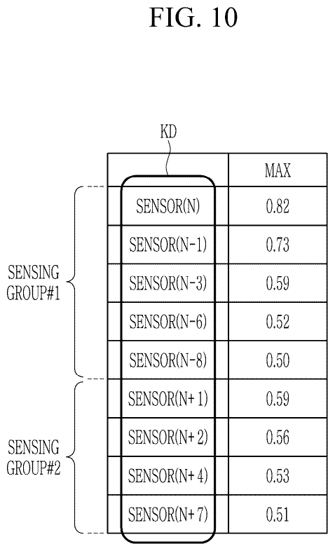

FIG. 10 is a diagram showing key data according to one embodiment.

Referring to FIG. 10, the key data KD may include multiple sensors SENSOR(N−8), SENSOR(N−6), SENSOR(N−3), SENSOR(N−1), SENSOR(N), SENSOR(N+1), SENSOR(N+2), SENSOR(N+4), and SENSOR(N+7) that may be separated and arranged by sensing group SENSOR GROUP #1 and SENSOR GROUP #2). By sorting the key data KD based on the sensing groups SENSOR GROUP #1 and SENSOR GROUP #2, the sensing groups SENSOR GROUP #1 and SENSOR GROUP #2 that are likely to cause dose errors can be quickly identified.

The first sensing group SENSOR GROUP #1 included in the key data KD may include an Nth sensor SENSOR(N), an N−1th sensor SENSOR(N−1), an N−3rd sensor SENSOR(N−3), an N−6th sensor SENSOR(N−5), and an N−8th sensor SENSOR(N−8). The Nth sensor SENSOR(N), the N−1th sensor SENSOR(N−1), the N−3rd sensor SENSOR(N−3), the N−6th sensor SENSOR(N−6), and the N−8th sensor SENSOR(N−8) may correspond to the Nth row, the N−1st row, the N−3rd row, the N−6th row, and the N−8th row, respectively, where the maximum value of the time series data is 0.5 or greater.

The second sensing group SENSOR GROUP #2 included in the key data KD may include an N+1st sensor SENSOR(N+1), an N+2nd sensor SENSOR(N+2), an N+4th sensor SENSOR(N+4), and an N+7th sensor SENSOR(N+7). The N+1st sensor SENSOR(N+1), the N+2nd sensor SENSOR(N+2), the N+4th sensor SENSOR(N+4), and the N+7th sensor SENSOR(N+7) may correspond to the N+1st row, the N+2nd row, the N+4th row, and the N+7th row, respectively, where the maximum value of the time series data has a value greater than or equal to 0.5.

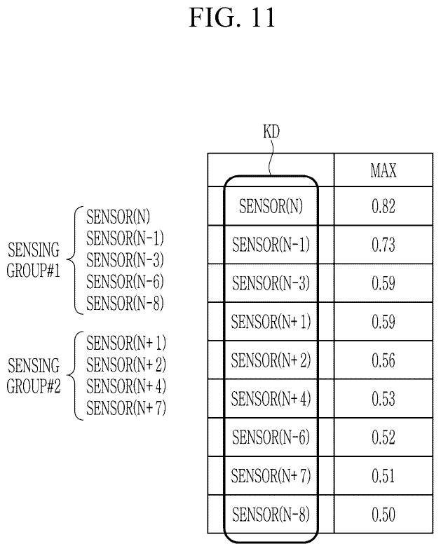

FIG. 11 is a diagram showing key data according to one embodiment.

Referring to FIG. 11, the key data KD may include multiple sensors SENSOR(N−8), SENSOR(N−6), SENSOR(N−3), SENSOR(N−1), SENSOR(N), SENSOR(N+1), SENSOR(N+2), SENSOR(N+4), and SENSOR(N+7) that may be sorted based on the maximum value of the time series data. At this time, the key data KD may not be sorted separately by sensing group SENSOR GROUP #1 and SENSOR GROUP #2. By sorting the key data KD based on the maximum value of the time series data, error risk sensors that are likely to cause dose errors can be quickly identified.

The maximum value of the time series data of the Nth row corresponding to the Nth sensor SENSOR(N) is 0.82, the maximum value of the time series data of the N−1th row corresponding to the N−1th sensor SENSOR(N−1) is 0.73, and the maximum value of the time series data of the N−3th row corresponding to the N−3th sensor SENSOR(N−3) is 0.59. The maximum value of the time series data of the N+1st row corresponding to the N+1st sensor SENSOR(N+1) is 0.59, the maximum value of the time series data of the N+2nd row corresponding to the N+2nd sensor SENSOR(N+2) is 0.56, and the maximum value of the time series data of the N+4th row corresponding to the N+4th sensor SENSOR(N+4) is 0.53. The maximum value of the time series data of the N−6th row corresponding to the N−6th sensor SENSOR(N−6) is 0.52, the maximum value of the time series data of the N−7th row corresponding to the N−7th sensor SENSOR(N+7) is 0.51, and the maximum value of the time series data of the N−8th row corresponding to the N−8th sensor SENSOR(N−8) is 0.50. Accordingly, the key data KD may sequentially include the Nth sensor SENSOR(N), the N−1st sensor SENSOR(N−1), the N−3rd sensor SENSOR(N−3), the Nth 1st sensor SENSOR(N+1), the Nth 2nd sensor SENSOR(N+2), the Nth 4th sensor SENSOR(N+4), the N−6th sensor SENSOR(N−6), the Nth 7th sensor SENSOR(N+7), and the N−8th sensor SENSOR(N−8).

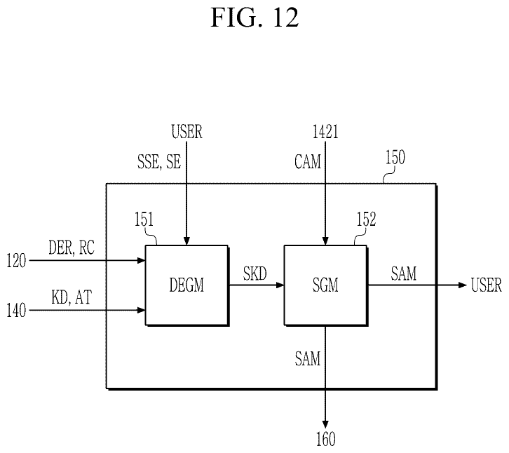

FIG. 12 is a block diagram of a visualization module according to one embodiment.

Referring to FIG. 12, the visualization module 150 may include a dose error graphic module (DEGM) 151 and a Sensor Activation Mapping (SAM) graphic module (SGM) 152.

The dose error graphic module 151 may receive a dose error rate DER and a dose error cause RC from the error detection module 120. The dose error graphic module 151 may display the dose error rate DER of a shot differently for each process. The dose error graphic module 151 may display a dose error cause RC corresponding to a shot in which a dose error occurred. The dose error graphic module 151 may receive a shot selection signal SSE for selecting a shot from a user USER.

The dose error graphic module 151 may receive key data KD and the sensor activation time AT from the analysis module 140. The dose error graphic module 151 may display key data KD. The dose error graphic module 151 may display the time of occurrence of a dose error corresponding to the initial section of the sensor activation time AT.

The dose error graphic module 151 may receive a selection signal SE for a user USER to select at least one row among a plurality of rows included in the key data KD. The dose error graphic module 151 may determine selection data SKD based on the selection signal SE. The dose error graphic module 151 may display selection data SKD. The dose error graphic module 151 may transmit selection data SKD to the SAM graphic module 152.

The SAM graphic module 152 may receive selection data SKD from the dose error graphic module 151. The SAM graphic module 152 may receive a CAM image CAM from the CAM generator 1421. The SAM graphic module 152 may generate a SAM image SAM based on selection data SKD and a CAM image CAM. The SAM graphic module 152 may obtain a sensor selected by the user USER from the selection data SKD. The SAM graphic module 152 may generate a SAM image SAM by extracting only the image of the row corresponding to the sensor selected by the user USER from the CAM image CAM. The SAM graphic module 152 may transmit a SAM image SAM to a user USER. The SAM graphic module 152 may transmit a SAM image SAM to the setting module 160.

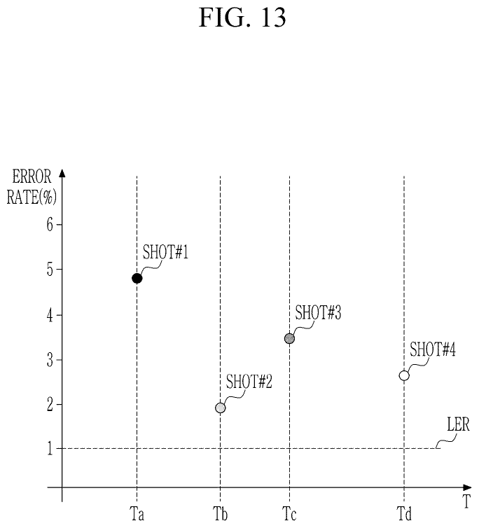

FIG. 13 is a diagram showing the dose error rate of a shot according to one embodiment.

Referring to FIG. 13, the dose error graphic module 151 described with reference to FIG. 12 may display multiple shots SHOT #1, SHOT #2, SHOT #3, and SHOT #4 in which a dose error rate DER exceeding a limit of error LER occurs. The multiple shots SHOT #1, SHOT #2, SHOT #3, and SHOT #4 may each be shots generated by different processes. The limit of error LER may mean the maximum value that a dose error may have within an acceptable range. For example, the limit of error LER might be 1%. The limit of error LER is not limited to this.

The dose error rate DER of the first shot SHOT #1 is 4.8%, and the dose error rate DER of the second shot SHOT #2 is 1.8%. The dose error rate DER of the third shot SHOT #3 may be 3.5%, and the dose error rate DER of the fourth shot SHOT #4 may be 2.6%.

The dose error graphic module 151 may display the dose error occurrence time T of multiple shots SHOT #1, SHOT #2, SHOT #3, and SHOT #4 in which a dose error rate DER occurs. For example, the time T of the dose error occurrence of the first shot SHOT #1 may be Ta, and the time T of the dose error occurrence of the second shot SHOT #2 may be Tb. The time T of the dose error occurrence of the third shot (SHOT #3) may be Tc, and the time T of the dose error occurrence of the fourth shot (SHOT #4) may be Td.

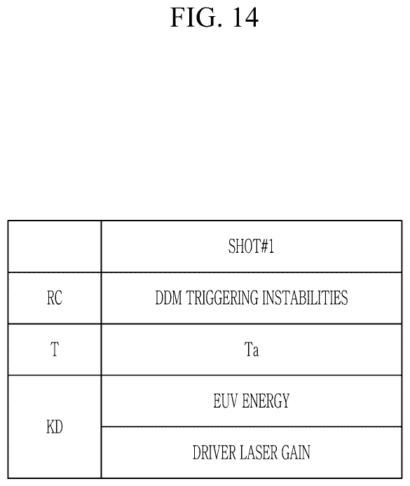

FIG. 14 is a diagram showing the cause of an error in a shot, the time of occurrence of a dose error, and key data according to one embodiment.

Referring to FIGS. 12 to 14, the dose error graphic module 151 may receive a shot selection signal SSE for selecting a first shot SHOT #1 from a user USER. The dose error graphic module 151 may display the dose error cause RC described with reference to FIGS. 12, the dose error occurrence time T, and key data KD for the first shot SHOT #1.

For example, the dose error graphic module 151 may indicate DDM triggering instability as the dose error cause RC for the first shot SHOT #1. The dose error graphic module 151 may display Ta as the dose error occurrence time T for the first shot SHOT #1. The dose error graphic module 151 may display the EUV energy sensor and driver laser gain sensor as key data KD for the first shot SHOT #1.

The dose error graphic module 151 may receive a selection signal SE for selecting at least one sensor among a plurality of sensors included in the key data KD from the user USER. For example, the dose error graphic module 151 may receive a selection signal SE for selecting an EUV energy sensor and a driver laser gain sensor from a user USER.

The dose error graphic module 151 may determine selection data SKD based on the selection signal SE. The dose error graphic module 151 may transmit selection data SKD to the SAM graphic module 152. The SAM graphic module 152 may generate a SAM image SAM based on selection data SKD and a CAM image CAM.

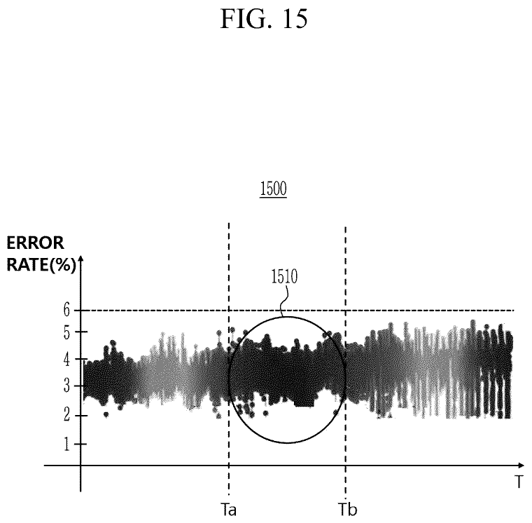

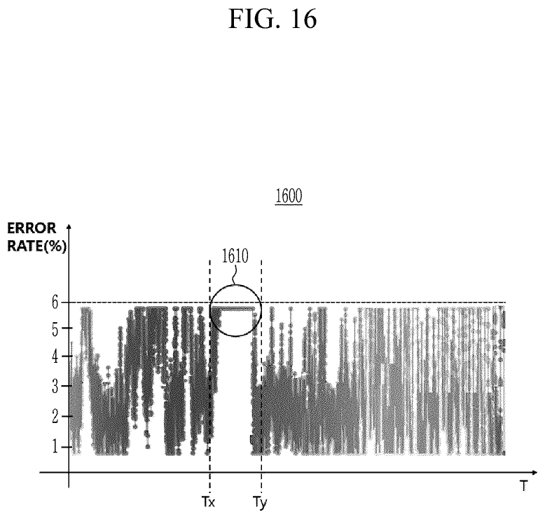

FIGS. 15 and 16 are drawings showing a first SAM image and a second SAM image, respectively.

FIG. 15 is a first SAM image 1500 generated by extracting a row corresponding to an EUV energy sensor selected by a user USER from a CAM image CAM by a SAM graphic module 152. FIG. 15 is a second SAM image 1600 generated by extracting a row corresponding to a driver laser gain sensor selected by a user USER from a CAM image CAM by a SAM graphic module 152.

The setting module 160 described with reference to FIG. 12 may receive a first SAM image 1500 and a second SAM image 1600 from the SAM graphic module 152. The first SAM image 1500 and the second SAM image 1600 may include a first waveform 1510 and a second waveform 1610, respectively. The first waveform 1510 and the second waveform 1610 may be waveforms for a region in which the time series data values of the EUV laser sensor and the driver laser gain sensor are equal to or greater than the first reference value, respectively.

The time series data values of the EUV laser sensor may be highest during the Ta~Tb period. The waveform of the EUV laser sensor during the Ta~Tb period may be the first waveform 1510. The time series data values of the driver laser gain sensor may be highest during the period Tx~Ty. The waveform of the EUV laser sensor during the Tx~Ty period may be the second waveform 1610.

The setting module 160 may analyze the cause of the dose error cause RC described with reference to FIG. 12 of the first shot SHOT #1 described with reference to FIG. 13 based on the first SAM image 1500 and the second SAM image 1600. The setting module 160 may provide actions to resolve dose error cause RC.

For example, if the first waveform 1510 of the EUV laser sensor in the first SAM image 1500 has no peak and the second waveform 1610 corresponding to the driver laser gain sensor in the second SAM image 1600 is saturated, the setting module 160 may determine that the dose error cause RC of the first shot SHOT #1 is DDM (Dynamic Dose Monitor) triggering instability. The setting module 160 may increase the value of the dose margin as an action to address DDM triggering instability.

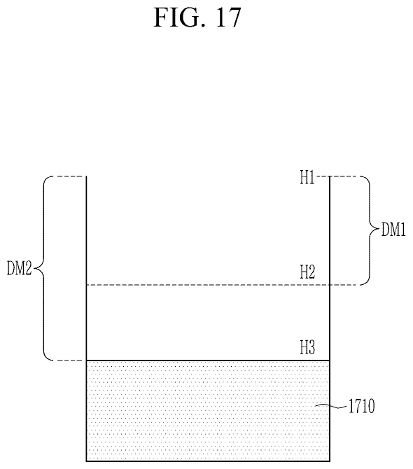

FIG. 17 is a diagram showing the relationship between the dose margin and the driver laser gain sensor.

Before explaining the contents of FIG. 17, the relationship between the output power of the driver laser and the dose margin will be described.

The output power of the driver laser may be determined based on process requirements including dose margin. If the dose margin is set wide to maintain the output stability of the driver laser, the output power of the driver laser may be lowered. As the output power of the driver laser decreases, the amount of EUV energy 1710 delivered to the shot may decrease. Accordingly, the output power adjustment range of the driver laser may be expanded.

Referring to FIGS. 16 and 17, the setting module 160 may provide an action to expand the output power adjustment range of the driver laser when the second waveform 1610 corresponding to the driver laser gain sensor is saturated. The setting module 160 may increase the value of the dose margin as an action to expand the output power adjustment range of the driver laser.

For example, the first dose margin DM1 may have a value of H1-H2. The second dose margin DM2 may have a value of H1-H3. The second dose margin DM2 may be larger than the first dose margin DM1 by H2-H3. The setting module 160 may change the existing first dose margin DM1 to the second dose margin DM2 as an action to expand the output power adjustment range of the driver laser.

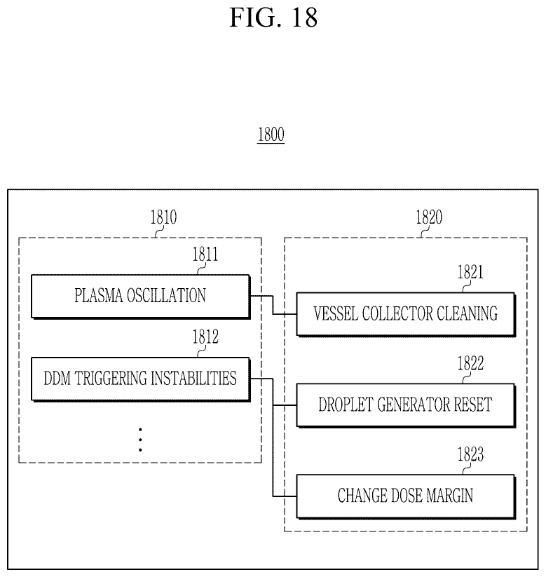

FIG. 18 is a diagram illustrating a portion of a labeled action according to one embodiment.

Referring to FIG. 18, an error cause group 1810 may include plasma vibration 1811 and DDM triggering instability 1812 as dose error causes (RC of FIG. 12). An action group 1820 may include actions to resolve the dose error cause RC including vessel collector cleaning 1821, droplet generator reset 1822, and change dose margin 1823. The types and number of dose error cause RC and actions included in each error cause group 1810 and the action group 1820 are not limited thereto.

There may be multiple actions to resolve the same dose error cause RC. Even if the dose error cause RC is the same, the error risk sensor included in the key data KD described with reference to FIG. 7 may be different. Accordingly, the multiple actions for calibrating different error risk sensors may also differ from each other.

Actions labeled with multiple dose error cause RC included in the error cause group 1810 may be utilized for CNN input image CIM learning of the analysis module 140 described with reference to FIG. 5. The setting module 160 may label the vessel collector cleaning 1821 as an action to address the plasma vibration 1811 in the plasma vibration 1811. The setting module 160 may label the droplet generator reset 1822 as an action to address the DDM triggering instability 1812 in the DDM triggering instability 1812. The setting module 160 may label the change dose margin 1823 as an action to resolve the DDM triggering instability 1812 as a DDM triggering instability 1812. At this time, the droplet generator reset 1822 and the change dose margin 1823 may correct different error risk sensors.

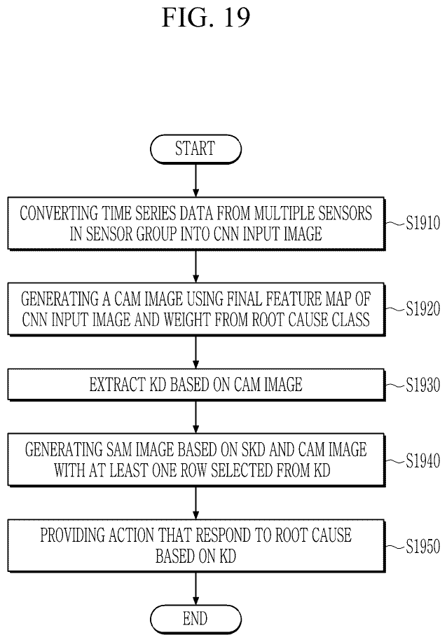

FIG. 19 is a flowchart showing a dose error checking method in one embodiment.

Referring to FIG. 19, in step S1910, the dose error checking device 100 described with reference to FIG. 1 may convert time series data of multiple sensors included in a sensing group into a CIM described with reference to FIG. 2. The dose error checking device 100 may convert raw data RD described with reference to FIG. 2 generated by measuring dose error shots with multiple sensors into a structured form to generate parsed data PD described with reference to FIG. 2. The dose error checking device 100 may sort parsed data PD based on sensing groups. The dose error checking device 100 may generate a CNN input image CIM based on parsed data PD.

In step S1920, the dose error checking device 100 may generate a CAM image CAM described with reference to FIG. 7 using the final feature map FFM described with reference to FIG. 6 for the CNN input image CNN and error cause class-specific weight CW described with reference to FIG. 7.

In step S1930, the dose error checking device 100 may extract key data KD described with reference to FIG. 7 based on the CAM image CAM. The dose error checking device 100 may extract a row among multiple rows included in a CAM image CAM in which the maximum value of time series data is greater than or equal to a first reference value. The dose error checking device 100 may generate key data based on rows in which the maximum value of time series data is greater than or equal to a first reference value. Key data KD may contain rows corresponding to error risk sensors. Key data KD may be sorted based on the maximum value of the time series data.

In step S1940, the dose error checking device 100 may generate a SAM image SAM described with reference to FIG. 12 based on the key data KD, the selection data SKD described with reference to FIG. 12 that selects at least one row from the key data KD, and the selection data SKD and the CAM image CAM. The dose error checking device 100 may provide a SAM image SAM to a user USER described with reference to FIG. 12.

In step S1950, the dose error checking device 100 may provide an action corresponding to the dose error cause RC described with reference to FIG. 12 based on the key data KD. The dose error checking device 100 may analyze the cause of the dose error RC based on the SAM image SAM. The dose error checking device 100 may provide an action to resolve the dose error cause RC. The dose error checking device 100 may label actions for dose error cause RC and utilize them for CNN input image CIM learning.

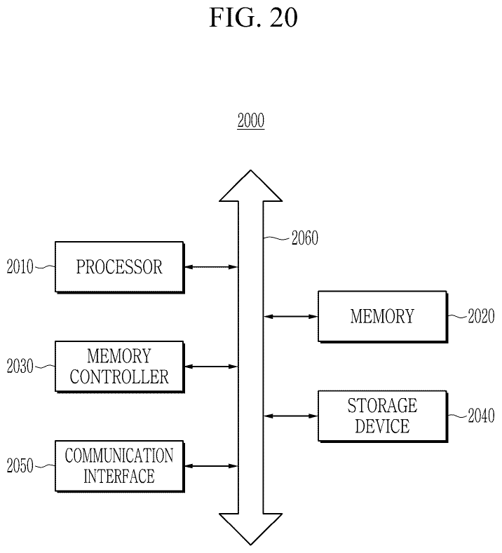

FIG. 20 is an example block diagram illustrating a computer device according to one embodiment.

Referring to FIG. 20, a computing device 2000 includes a processor 2010, memory 2020, a memory controller 2030, a storage device 2040, a communication interface 2050, and a bus 2060. The computing device 2000 may further include other general-purpose components.

The processor 2010 controls the overall operation of each component of the computing device 2000. The processor 2010 may be implemented with at least one of various processing units, such as a central processing unit CPU, an application processor AP, and a graphic processing unit GPU.

The processor 2010 may extract from the CAM image CAM described with reference to FIG. 7, the error risk sensors that cause dose error RC described with reference to FIG. 12. The processor 2010 may generate key data KD described with reference to FIG. 7 including an error risk sensor. The processor 2010 may provide actions to resolve the dose error cause RC.

Memory 2020 stores various data and commands. The memory 2020 may be implemented as a memory device as described with reference to FIGS. 1 to 19. The memory controller 2030 controls the transfer of data or commands to and from the memory 2020. In some embodiments, the memory controller 2030 may be provided as a separate chip from the processor 2010. In some embodiments, the memory controller 2030 may be provided as an internal component of the processor 2010.

The storage device 2040 non-temporarily stores programs and data. In some embodiments, the storage device 2040 may be implemented as non-volatile memory. The communication interface 2050 supports wired and wireless Internet communication of the computing device 2000. Additionally, the communication interface 2050 may support various communication methods other than Internet communication. The bus 2060 provides communication capabilities between components of the computing device 2000. The bus 2060 may include at least one type of bus 2060 depending on the communication protocol between the components.

While this disclosure contains many specific embodiment details, these should not be construed as limitations on the scope of what may be claimed. Certain features that are described in this disclosure in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A dose error checking device comprising:
a memory configured to store raw data from multiple sensors, the multiple sensors being configured to measure dose error shots; and
a processing circuit configured to:
sort the raw data into a sensing group to generate a convolutional neural network (CNN) input image,
generate a class activation mapping (CAM) image based on (i) a final feature map corresponding to the CNN input image and (ii) a respective weight for each error cause class,
generate, based on the CAM image, key data that include at least one row corresponding to at least one error risk sensor of the multiple sensors, and
display a sensor activation mapping (SAM) image corresponding to a selected error risk sensor of the at least one error risk sensor, the SAM image being based on the key data, selection data that select at least one row of the key data, and the CAM image.

2. The dose error checking device of claim 1, wherein the processing circuit comprises:
a raw data analyzer configured to convert the raw data into a structured form to generate parsed data; and
a converter configured to sort the parsed data based on the sensing group and generate the CNN input image based on the parsed data.

3. The dose error checking device of claim 2, wherein
the converter is configured to align the parsed data such that the parsed data of at least one sensor with a same physical unit are adjacent to one another.

4. The dose error checking device of claim 3, wherein
the sensing group comprises:
a first sensing group including a plurality of sensors configured to sense an action of generating a droplet and delivering the droplet to a location;
a second sensing group including a plurality of sensors configured to sense an action of monitoring an energy level of a laser;
a third sensing group configured to sense interference (i) between the laser and a main pulse and (ii) between the laser and a pre-pulse; and
a fourth sensing group configured to amplify a power level of a seed laser and a driver laser.

5. The dose error checking device of claim 4,
wherein the first sensing group includes an X-axis sensor for sensing an X-axis distance between the laser and the droplet, a Y-axis sensor for sensing a Y-axis distance between the laser and the droplet, and a Z-axis sensor for sensing a Z-axis distance between the laser and the droplet,
wherein the second sensing group includes a main pulse pedestal energy sensor configured to control a main pulse pedestal energy of the laser and a main pulse power sensor configured to control an output power of the main pulse of the laser,
wherein the third sensing group includes a first focus sensor configured to control an X-axis distance between a focus of the main pulse and a focus of the pre-pulse, and a second focus sensor configured to control a Y-axis distance between the focus of the main pulse and the focus of the pre-pulse, and
wherein the fourth sensing group includes a driver laser gain sensor configured to control an amplification intensity of the driver laser and a power amplifier gain sensor configured to control an amplification capability of a power amplifier.

6. The dose error checking device of claim 2, wherein
the processing circuit includes:
a classifier configured to extract the final feature map through a convolution and pooling process based on the CNN input image, and classify a cause of error by multiplying an average value of the final feature map by the respective weight for each error cause class; and
a key data generator configured to generate the CAM image by multiplying the final feature map by the respective weight for each error cause class, and generate the key data that have a value greater than a first reference value in the CAM image.

7. The dose error checking device of claim 6, wherein
the key data generator includes:
a CAM generator configured to receive, from the classifier, the final feature map and the respective weight for each error cause class associated with the CNN input image, multiply the final feature map by the respective weight for each error cause class to generate a plurality of second final feature maps, and generate the CAM image by adding the plurality of second final feature maps;
a smoothing module configured to apply Gaussian blur to the CAM image to generate a second CAM image; and
a filtering module configured to
filter in at least one row of a plurality of rows of the second CAM image, each of the at least one filtered row having a maximum value of time series data greater than a first reference value, and
generate the key data that include the at least one filtered row, the at least one filtered row corresponding to the at least one error risk sensor.

8. The dose error checking device of claim 7, wherein
the filtering module is configured to filter in at least one row each having the maximum value of time series data equal to or greater than 0.5.

9. The dose error checking device of claim 8, wherein
the at least one filtered row includes a plurality of rows, and the filtering module is configured to separate and sort the key data based on the sensing group.

10. The dose error checking device of claim 9, wherein
the filtering module is configured to sort the key data based on the maximum value of the time series data.

11. The dose error checking device of claim 6, wherein
the processing circuit includes:
a dose error graphic module configured to obtain the key data from the key data generator and display the selection data; and
a SAM graphic module configured to receive the selection data from the dose error graphic module, receive the CAM image from the key data generator, generate the SAM image based on the selection data and the CAM image, and display the SAM image, wherein the SAM imaging corresponds to the selected error risk sensor.

12. The dose error checking device of claim 11, wherein
the dose error graphic module is configured to display an error cause and a dose error occurrence time corresponding to a dose error shot associated with the error cause.

13. A dose error checking device comprising:
a processing circuit configured to generate key data based on a final feature map and a respective weight for each class of dose error causes,
wherein the final feature map is based on a convolution and pooling process for a convolutional neural network (CNN) input image,
wherein the key data include class activation mapping (CAM) image and a row corresponding to an error risk sensor from the CAM image,
wherein the processing circuit is configured to
display a sensor activation mapping (SAM) image that corresponds to the error risk sensor, the SAM image being based on (i) selection data that select at least one row of the key data and (ii) the CAM image;
analyze a cause of a dose error based on the SAM image; and
provide an action to resolve the cause of the dose error.

14. The dose error checking device of claim 13,
wherein the selection data includes data indicating an extreme ultraviolet (EUV) laser sensor and a driver laser gain sensor,
wherein the processing circuit is configured to:
display a first SAM image corresponding to the EUV laser sensor and a second SAM image corresponding to the driver laser gain sensor;
determine that the cause of the dose error is dynamic dose monitor (DDM) triggering instability; and
determine, as the action to resolve the cause of the dose error, an action of increasing a value of a dose margin based on a first waveform corresponding to the EUV laser sensor in the first SAM image being free of a peak and a second waveform corresponding to the driver laser gain sensor in the second SAM image being saturated.

15. The dose error checking device of claim 14, wherein
the processing circuit is configured to label, for a CNN training, the action of increasing the value of the dose margin as training data that are associated with the DDM triggering instability.

16. A method of checking a dose error comprising:
generating, using a processing circuit, a convolutional neural network (CNN) input image by arranging, based on a sensing group, raw data generated by multiple sensors for measuring dose error shots;
generating, using the processing circuit, a class activation mapping (CAM) image based on a final feature map and a respective weight for each error cause class, the final feature map corresponding to the CNN input image;
generating, using the processing circuit, a key data including at least one row of the CAM image, the at least one row corresponding to at least one error risk sensor; and
displaying, using the processing circuit, a sensor activation mapping (SAM) image that corresponds to an error risk sensor of the at least one error risk sensor, the SAM image being based on the key data, selection data that select at least one row from the key data, and the CAM image.

17. The method of claim 16, wherein
generating the CNN input image includes:
converting the raw data into a structured form to generate parsed data; and
sorting the parsed data based on the sensing group and generating the CNN input image based on the parsed data.

18. The method of checking a dose error of claim 17, wherein
generating the key data comprises:
generating the key data that have a value greater than or equal to a first reference value in the CAM image.

19. The method of checking a dose error of claim 18, comprising:
sorting the key data based on a maximum value of time series data.

20. The method of checking a dose error of claim 18, wherein
displaying the SAM image comprises:
obtaining the key data corresponding to a dose error shot of the dose error shots and displaying the selection data.
